(19) United States
(12) Patent Application Publication
(10) Pub. No.: US 2011/0233719 A1
(43) Pub. Date: Sep. 29, 2011

(54) TEST METHOD ON THE SUPPORT SUBSTRATE OF A SUBSTRATE OF THE "SEMICONDUCTOR ON INSULATOR" TYPE

(75) Inventor: Chrystelle Lagahe Blanchard, Crolles (FR)

(73) Assignee: S.O.I.TEC SILICON ON INSULATOR TECHNOLOGIES, Crolles Cedex (FR)

(21) Appl. No.: 13/133,118

(22) PCT Filed: Jan. 14, 2010
(86) PCT No.: PCT/EP2010/050408

§ 371 Date: Jun. 8, 2011

(30) Foreign Application Priority Data
Jan. 19, 2009 (FR) 0950296

(51) Int. Cl. H01L 29/06; H01L 21/02; H01L 21/762; H01L 21/66

(52) U.S. Cl. 257/506; 438/466; 438/455; 438/14; 257/E21.002; 257/E21.567; 257/E21.521; 257/E29.02

(57) ABSTRACT

The invention relates to a test method comprising an electrical connection contact on the support of a substrate of the semiconductor-on-insulator type.

This method is remarkable in that it comprises the steps of:
a) taking a substrate of the semiconductor-on-insulator type comprising a support substrate entirely covered with an insulator layer and an active layer, a portion of the insulator layer being buried between the active layer and the front face of the support substrate,
b) removing a portion of the insulator layer that extends at the periphery of the front face of the support substrate and/or that extends on its rear face, so as to delimit at least one insulator-free accessible area of the support substrate, while retaining at least one portion of the insulator layer on the rear face,
c) applying an electrical voltage to the accessible area in order to make the electrical connection contact.

### CROSS-REFERENCE TO RELATED APPLICATIONS

This is a national phase entry under 35 U.S.C. §371 of International Patent Application PCT/EP2010/050408, filed Jan. 14, 2010, published in English as International Patent Publication WO 2010/081852 A1 on Jul. 22, 2010, which claims the benefit under Article 8 of the Patent Cooperation Treaty to French Patent Application Serial No. 0950296, filed Jan. 19, 2009, the entire disclosure of which is hereby incorporated herein by this reference.

### TECHNICAL FIELD

The invention is located in the field of manufacturing of electronic components, in particular, a substrate known under the acronym of “SeOI” from the expression “Semiconductor-On-Insulator.”

The present invention more particularly relates to a test method that comprises the fact of making an electric connection contact on the support substrate of a substrate of the SeOI type.

### BACKGROUND

In the following description and claims, by “substrate of the SeOI type” is meant a substrate that successively comprises a support substrate in a semiconducting material, entirely covered with an insulator layer, notably of oxide or nitride, and another layer of semiconducting material, a so-called “active layer,” in or on which electronic components are or will be formed. A portion of this insulator layer is thus buried between the active layer and one of the faces of the support substrate, a so-called “front face.”

Such a substrate 1 is illustrated in enclosed FIG. 1. It comprises a support substrate 2 in a semiconducting material entirely covered with an insulator layer 3 and an active layer 4 of semiconducting material.

The portion of the insulator layer 3 located facing one of the faces of the support substrate 2, a so-called “front face 21,” is referenced as 31. As this may be seen in the figure, part of the portion 31 of the insulator layer 3 is buried between the active layer 4 and the front face 21 of the support substrate 2.

The opposite face of the support substrate 2, called “rear face,” bears reference 22. The portion of the insulator layer 3 located facing the rear face 22 bears the numerical reference 32, while the one located at the periphery of the support substrate 2 is referenced as 33.

The insulator layer 3 may, for example, be formed with an oxide, nitride or oxynitride. In the case when the semiconducting material forming the support substrate 2 and/or the active layer 4 is silicon, the insulator advantageously is silicon oxide (SiO₂) or silicon nitride (Si₃N₄).

Informatively, it will be noted that all the SeOI substrates do not have an insulating layer over the whole surface of the support substrate. This notably concerns “thick” SeOIs, i.e., SeOIs for which it is desired to have a relatively thick buried insulator thickness (from 1 micron to a few micrometers). For this type of SeOI substrates, it is customary to form an insulator (for example, by oxidation), both on the “support” substrate and on the “donor” substrate before their assembling by bonding, so that after thinning the donor substrate, the support of the SeOI is entirely covered with an insulator. This type of substrate is directed to power applications, for example, the formation of components that process high power signals.

### SUMMARY OF THE INVENTION

The invention applies to SeOI substrates, the support substrate of which is entirely covered with an insulator layer.

During the processes for manufacturing electronic components, it is sometimes useful to have access to the rear face 22 of the support substrate 2, for example, in order to carry out electric tests of the components elaborated on the front face 21; these tests may notably require application of electric voltage at the rear face 22. To do this, it is then necessary to remove the portion 32 of insulator layer 3 present on the rear face 22 of the support substrate 2.

Now, the applicant has seen that when the portion 32 of insulator layer 3 on the rear face 22 is removed, the SeOI substrate deforms and assumes a slightly cambered shape.

This deformation or “camber” is known under the name of “warp” or “warpage” and it increases with the increase in the thickness of the buried portion 31 of insulator layer 3.

In other words, the forces or stresses present inside the SeOI substrate are no longer compensated when the insulator layer 32 of the rear face is removed.

FIG. 2 illustrates the substrate of FIG. 1 after removing a portion of the insulator layer by wet chemical etching, this substrate exhibiting the “warpage” phenomenon. The stresses exerted by portion 31 of insulator layer 3 are no longer compensated by the presence of the portion 32 of insulator layer 3 and the SeOI substrate 1 tends to deform by becoming concave with concavity oriented towards the rear face 22 of the support substrate 2, notably in the case of a BSOI structure (support and active layer in silicon and insulator in silicon oxide).

The “warpage” is measured at the concave portion of the support substrate 2. It corresponds to the distance a between a plane P passing through the edges of the concavity, i.e., the edges of the support substrate 2 and the deepest point of the concavity, generally located in the center of the support substrate 2.

“Warpage” distance a is measured by different techniques well known to one skilled in the art, i.e., optical or mechanical profilometry or capacitive thickness measurement techniques.

As an example, mention may be made of capacitive measurements using a piece of equipment known under the name of “Wafersight” from the manufacturer ADE (henceforth called KLA Tencor), which allow measurement of the thickness and deformation of a substrate. The warpage may also be measured by an optical measurement, for example, with a piece of equipment known as FLEXUS, produced by the same manufacturer, which allows the surface of the support substrate to be scanned.

As an example, reference may be made to a substrate known to the person skilled in the art under the acronym of “BSOI,” which means “Bonded Silicon-On-Insulator” and designates a substrate of the Silicon-On-Insulator” type obtained by bonding two silicon substrates, at least one of which (the support) has an oxidized surface, and then by thinning one of the two substrates in order to form the active layer. It was possible to measure that such a substrate, for example, comprising buried oxide portion 31 with a thickness of the 2.5 μm, may attain a warpage of the order of 150 μm when the oxide portion 32 of the rear face is removed, while it has a warpage a of less than 30 μm in the case when this oxide remains in place.

Now, significant warpage induces problems for gripping the substrates with robots, as well as problems for positioning the substrates on retaining members or planar supports, during their subsequent use.

This warpage occurrence phenomenon is described in U.S. Pat. No. 5,780,311, in the case of an SOI type substrate after disappearance of the oxide layer present on the rear face of the support substrate. However, the recommended solution only consists of protecting this oxide layer by depositing a protective layer made in polycrystalline or amorphous silicon, in nitride or in photosensitive resin.

Now, this solution cannot be applied in a test method that has exactly the goal of forming insulator-free electric connection contact areas.

The object of the invention is, therefore, to provide a test method with which an electric connection contact may be made on an SeOI substrate, and an electric voltage may be applied to the support substrate, while limiting to a maximum the warpage phenomenon of this substrate.

Preferably, the object of the invention is to limit the phenomenon of warpage to a value of less than 100 μm, still preferably less than 50 μm.

This object is achieved by a test method comprising an electrical connection contact on the support substrate of a substrate of the semiconductor-on-insulator type.

According to the invention, this method comprises the steps of:
a) taking a substrate of the semiconductor-on-insulator type comprising a support substrate in a semiconducting material entirely covered with an insulator layer and a so-called “active” layer of semiconducting material, positioned on the support substrate so that a portion of the insulator layer is buried between the active layer and one of the faces, a so-called “front” face, of the support substrate,
b) removing a portion of the insulator layer that extends at the periphery of the front face of the support substrate and/or that extends on its so-called “rear” opposite face, so as to delimit at least one insulator-free area of the support substrate, a so-called “accessible area,” while retaining at least one portion of the insulator layer on the rear face,
c) applying an electric voltage to one or to at least some of the accessible areas, so as to make electric connection contact on the support substrate of the semiconductor-on-insulator substrate.

According to other advantageous and non-limiting characteristics of the invention, taken alone or as a combination:
the portion of the insulator layer that is removed in step b) is taken at the annular insulator area extending at the periphery of the rear face of the support, and/or at the annular insulator layer that extends at the periphery of the front face of the support around the active layer;
at least 50% of the surface area of the insulator layer of the rear face is retained, during application of step b);
step b) consists of carrying out routing of the annular region of the insulator layer extending at the periphery of the front face of the support substrate, this routing being carried out over a width comprised between 0.5 mm and 5 mm and/or of carrying out routing of the annular region of the insulator layer extending at the periphery of the rear face of the support substrate, this routing being carried out over a width comprised between 0.5 mm and 15 mm;
removal of the insulator is carried out by grinding and/or polishing;
removal of the insulator is carried out by lithography and/or chemical etching;
removal of the insulator is carried out during the manufacturing of electronic components on and/or in the active layer;
removal of the insulator is carried out after manufacturing the semiconductor-on-insulator substrate and before manufacturing electronic components on and/or in the active layer;
the semiconductor-on-insulator substrate is obtained by bonding the support substrate covered with the insulator layer and a source substrate from which stems the active layer and in that the removal of the insulator is carried out during the manufacturing of the semiconductor-on-insulator substrate, after heat treatment for stabilizing the bond of both substrates;
the insulator is an oxide, nitride or oxynitride.

The invention also relates to a test substrate of the semiconductor-on-insulator type comprising a support substrate in a semiconducting material covered with an insulator layer and a so-called “active” layer of semiconducting material, positioned on the support substrate so that a portion of the insulator layer is buried between the active layer and one of the faces, a so-called “front” face, of the support substrate.

According to the invention, a portion of the support substrate is free of insulator so that it is exposed, at least one portion of the rear face of the support substrate being covered with the insulator layer and the substrate has warpage distance a of less or equal to 50 μm.

Further, advantageously:
the insulator layer that extends on the rear face of the support substrate extends over at least 50% of the surface area of this rear face,
the buried insulator layer of this test substrate has a thickness greater than or equal to 0.2 μm, still preferably greater than or equal to 1 μm.

Other characteristics and advantages of the invention will become apparent from the description which will now be made of it, with reference to the appended drawings, which illustrate as an indication but not as a limitation, several possible embodiments thereof

### BRIEF DESCRIPTION OF THE DRAWINGS

In these drawings:

FIG. 1 is a diagram illustrating an SeOI type substrate, in a cross-sectional view,

FIG. 2 is a diagram illustrating the warpage phenomenon observed on the substrate of FIG. 1, after removing a portion of the insulator layer by wet chemical etching,

FIGS. 3-5 are diagrams illustrating SeOI type substrates in cross-sectional views, after formation of areas providing an electric connection contact on the support substrate, according to three different embodiments of the method according to the invention,

FIG. 6 is a top view of the SeOI substrate of FIG. 3, at a smaller scale,

FIG. 7 is a bottom view of the substrate of FIG. 5, at a smaller scale, and

FIG. 8 is a bottom view of an SeOI type substrate illustrating an alternative of FIG. 7.

The aforementioned figures are schematic and the dimensions and thicknesses of the different layers are not illustrated at their actual relative values.

### DETAILED DESCRIPTION OF THE INVENTION

The test method according to the invention may be applied to any type of SeOI substrate, whether the latter has been obtained by the aforementioned BSOI type method or by another method, for example, one of the methods known under the name of SMART CUT or SIMOX, provided that the support substrate is actually surrounded by an insulator layer initially.

The test method according to the invention comprises the following steps:
a) taking a substrate 1 of type SeOI,
b) removing at least one portion of the annular region of the insulator layer 3 located at the periphery of the front face 21 or removing only a portion of the insulator layer 3 extending on the rear face 22 of the support substrate 2, in order to avoid occurrence of the warpage phenomenon,
c) applying an electric voltage to the area of the support substrate cleared during step b) (or to at least at some of them if there are several of them), so as to make an electric connection contact on the support substrate 2 of the SeOI substrate 1.

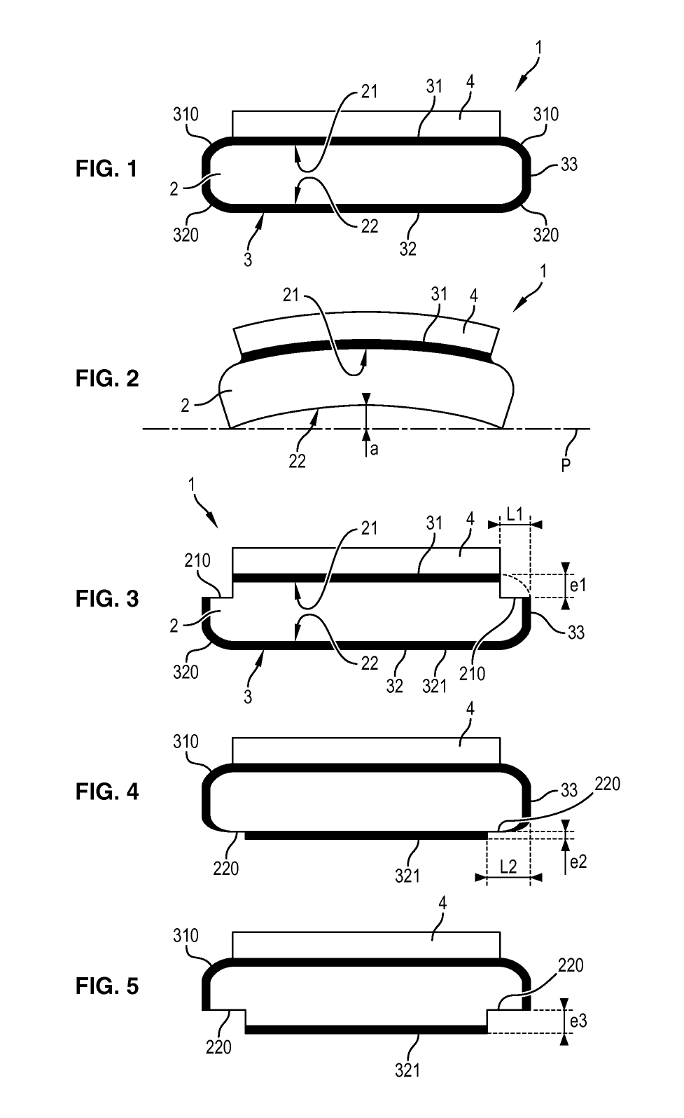

A first embodiment of step b) of the method according to the invention will now be described with reference to FIGS. 1, 3 and 6.

In FIG. 1, the active layer 4 is of a diameter slightly smaller than that of the support substrate 2, typically of less than 2-5 mm. This is due to the use of chamfered wafer for making an SeOI substrate, which do not allow bonding of both initial substrates up to the extreme edge. A so-called “exclusion” area, located on the front face, therefore, does not include any active layer. Accordingly, the front face 21 of the support substrate 2 is covered with an insulator layer that extends beyond the edges of the active layer 4 and that has an annular shape. This annular shape is referenced as 310.

Step b) consists of removing at least one portion of the annular region 310 of the insulator layer, so as to delimit at least one area of the support substrate 2 that is found free of insulator. This so-called “accessible” area bears the numerical reference 210.

Of course, this removal is not possible if the diameter of the active layer 4 is identical with that of the support substrate 2 covered with the insulator layer.

The surface area of the accessible area should be sufficiently large so as to allow an electric connection contact, for example, of at least a few square millimeters.

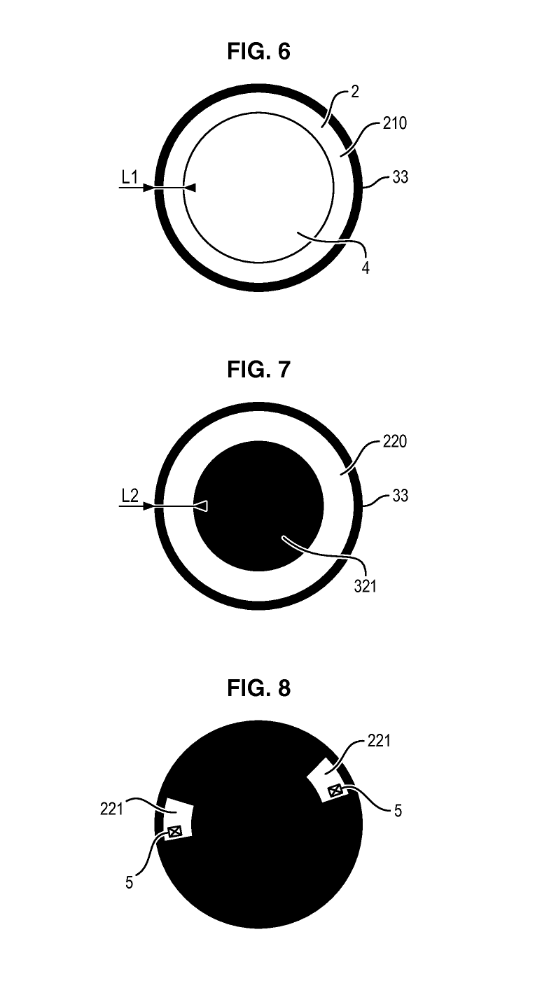

This routing operation allows either removal of the totality of the annular region 310, as illustrated in FIG. 6, or only of a portion, according to an alternative not shown in the figures. In the latter case, at least one accessible area 210, possibly several of them, are obtained on the periphery of the substrate. FIG. 8 illustrates a similar result obtained on the peripheral annular region of the rear face insulator portion 32.

As illustrated in FIG. 3, it is possible, depending on the technique used for removing the annular region 310, that a small thickness of the support substrate 2 located immediately below this annular region 310 should also be removed.

The annular region 310 preferably extends over a width L1 comprised between 0.5 and 5 mm starting from the edge of the substrate 1.

As an example, this width L1 generally comprises between 1 and 3 millimeters for a substrate with a 6-inch (about 15 centimeters) diameter and between 1 and 4 millimeters for an 8-inch (about 20 centimeters) substrate.

The depth of the removed area e1 is at least of the thickness of the annular region 310, i.e., of the order of a few micrometers, for example, 2 μm, and may attain 15 μm if a portion of the support substrate 2 is also removed, or even a few tens of micrometers.

A first technique for removing the insulator consists of carrying out grinding and/or polishing of the latter.

This grinding or polishing may be mechanical and/or chemical. In the case of mechanical grinding, the substrate 1 may, for example, be held on a support driven into rotation and also a rotating tool is brought in contact with the annular region in order to grind the latter. In the case of polishing, it is possible to use a polishing shoe combined with a suitable chemical solution.

The grinding technique generally results in the removal of the insulator layer and of a portion of the support substrate 2, while with polishing, it is possible to more specifically only remove the insulator layer.

A second technique consists of using lithographic steps followed by dry or wet chemical etching steps. This more selective technique enables removal of only the annular region 310, without etching the portion of the support substrate 2 located just below.

Finally, it will be noted that the insulator layer portion 32 is preferably retained on the rear face, which avoids the warpage phenomenon or else if a portion of it is removed, it is removed as explained hereafter.

A second embodiment of step b) will now be described with reference to FIGS. 4 and 7.

In this case, step b) consists of removing a portion of the insulator layer 32 of the rear face of the support substrate 2, while retaining at least one portion of this insulator layer on the rear face. Preferably, the retained portion corresponds to at least 50% of the total surface area of the insulator layer portion 32 covering the rear face 22 of the support substrate 2.

Preferentially, step b) consists of removing the totality (see FIG. 7) or a portion (see FIG. 8) of an annular region of the insulator layer 32, this annular region extending at the periphery of the rear face of the support substrate 2.

This annular region, visible before its removal on FIG. 1, bears numerical reference 320. This removal of the annular insulator layer 320 has the effect of clearing an accessible area 220 extending on the rear face of the support substrate 2.

This removal is applied by retaining at least the central portion of the insulator layer on the rear face. This central portion bears numerical reference 321.

The L2 of the removed annular region preferably comprises between 0.5 mm and 15 mm starting from the edge of the substrate 1.

As an example, L2 is comprised between 2 and 10 mm for a substrate with a diameter of 6 inches (about 15 cm) and between 2 and 15 mm for an 8-inch (about 20 cm) substrate.

The thickness e2 of the removed area corresponds to that of the insulator layer portion 32, i.e., of the order of a few micrometers, for example, 2 μm.

FIG. 5 illustrates an alternative in which a portion of the rear face 22 of the support substrate 2, located under the annular insulator portion 320 is also removed. In this case, the thickness e3 may attain 15 μm.

The techniques used for removing a portion of the annular insulator region 320 and possibly of the support substrate 2, are the same as those described earlier for the first embodiment.

In the embodiment illustrated in FIG. 8, only a portion of the annular region 320 of the insulator located on the rear face of the support substrate 2 has been removed. Two point-like accessible areas referenced as 221 are delimited.

The number of these cleared areas depends on subsequent tests to be conducted, and is, for example, related to the constraints of the equipment used or to the connection contact configurations.

The shape of the cleared areas is arbitrary and may be round, square or of another shape.

The point-like accessible areas 221 are preferably obtained by chemical etching through a mask comprising apertures that correspond to the shape of the accessible areas 221 to be obtained.

A fourth embodiment not shown in the figures may consist of clearing the edges of the support substrate at the periphery (area 33).

In all of the embodiments that have just been described, the step for removing at least one portion of the annular insulator region 310, 320 may be carried out and inserted in different stages of the method.

Thus, this removal may be carried out after manufacturing the semiconductor-on-insulator substrate 1, but before manufacturing electronic components on and/or in the active layer 4.

This removal may also be carried out during the manufacturing of electronic components on and/or in the active layer 4.

Finally, this removal may also be carried out during the manufacturing of the semiconductor-on-insulator substrate 1, after the support substrate 2 covered with the insulator layer 3 has been bonded on a source substrate and after heat treatment for stabilizing the bonding of both of these substrates, but before thinning the source substrate by which the active layer 4 may be obtained. It is also possible to contemplate preparation of the support substrate 2 in order to form the exposed areas before its bonding on the source substrate.

The last step of the method consists of applying an electric voltage to the accessible area and to at least some of the accessible areas, for example, by means of an electrode, as illustrated in FIG. 8, with the purpose of making an electric connection contact.

The main advantages of the method according to the invention are:
that access to accessible areas 210, 220 made on the support substrate 2 may be facilitated, while avoiding the warpage phenomenon on the SeOI substrate, the SeOI substrates obtained according to the method of the invention actually have warpage distance a of less than or equal to 50 μm;
that addition of an additional step for forming accessible areas 210, 220 is accomplished without modifying existing manufacturing processes, whether these are the methods for manufacturing the SeOI substrate or those for electronic components.

1.-13. (canceled)

14. A method, comprising:
providing a semiconductor-on-insulator substrate, comprising:
a support substrate including a semiconductor material, the support substrate having a front face and a rear face;
an insulator layer covering the support substrate; and
an active layer including a semiconductor material positioned on the support substrate such that a portion of the insulator layer is buried between the active layer and the front face of the support substrate;
removing a portion of the insulator layer that extends at the periphery of at least one of the front face and the rear face of the support substrate and delimiting at least one insulator-free accessible area of the support substrate while retaining at least one portion of the insulator layer on the rear face of the support substrate; and
applying an electrical voltage to the at least one insulator-free accessible area of the support substrate so as to make an electrical connection contact on the support substrate of the semiconductor-on-insulator substrate.

15. The method of claim 14, wherein removing the portion of the insulator layer that extends at the periphery of the at least one of the front face and the rear face of the support substrate comprises removing an annular insulator area extending along at least one of the front face and the rear face of the support substrate.

16. The method of claim 14, wherein retaining at least one portion of the insulator layer on the rear face of the support substrate comprises retaining at least 50% of a surface area of the insulator layer on the rear face of the support substrate.

17. The method of claim 14, wherein removing the portion of the insulator layer that extends at the periphery of the at least one of the front face and the rear face of the support substrate comprises routing an annular region of the insulator layer extending at a periphery of the front face of the support substrate.

18. The method of claim 17, wherein routing an annular region of the insulator layer extending at a periphery of the front face of the support substrate comprises routing an annular region of the insulator layer over a width of between 0.5 mm and 5 mm.

19. The method of claim 14, wherein removing the portion of the insulator layer that extends at the periphery of the at least one of the front face and the rear face of the support substrate comprises routing an annular region of the insulator layer extending at a periphery of the rear face of the support substrate.

20. The method of claim 19, wherein routing an annular region of the insulator layer extending at a periphery of the rear face of the support substrate comprises routing an annular region of the insulator layer over a width of between 0.5 mm and 15 mm.

21. The method of claim 14, wherein removing the portion of the insulator layer that extends at the periphery of the at least one of the front face and the rear face of the support substrate comprises at least one of grinding and polishing the portion of the insulator layer that extends at the periphery of the at least one of the front face and the rear face of the support substrate.

22. The method of claim 14, wherein removing the portion of the insulator layer that extends at the periphery of the at least one of the front face and the rear face of the support substrate comprises chemically etching the portion of the insulator layer that extends at the periphery of the at least one of the front face and the rear face of the support substrate.

23. The method of claim 14, wherein removing the portion of the insulator layer that extends at the periphery of the at least one of the front face and the rear face of the support substrate comprises using at least one lithography process to remove the portion of the insulator layer that extends at the periphery of the at least one of the front face and the rear face of the support substrate.

24. The method of claim 14, further comprising manufacturing at least one electronic component on or in the active layer while removing the portion of the insulator layer that extends at the periphery of the at least one of the front face and the rear face of the support substrate.

25. The method of claim 14, further comprising manufacturing the semiconductor-on-insulator substrate.

26. The method of claim 25, wherein removing the portion of the insulator layer that extends at the periphery of the at least one of the front face and the rear face of the support substrate comprises removing the portion of the insulator layer that extends at the periphery of the at least one of the front face and the rear face of the support substrate after manufacturing the semiconductor-on-insulator substrate.

27. The method of claim 26, further comprising manufacturing at least one electronic component on or in the active layer after removing the portion of the insulator layer that extends at the periphery of the at least one of the front face and the rear face of the support substrate.

28. The method of claim 25, wherein manufacturing the semiconductor-on-insulator substrate comprises bonding a source substrate to the support substrate covered with the insulator layer.

29. The method of claim 28, further comprising heat treating the source substrate and the support substrate to stabilize a bond between the source substrate and the support substrate.

30. The method of claim 29, further comprising removing the portion of the insulator layer that extends at the periphery of the at least one of the front face and the rear face of the support substrate while manufacturing the semiconductor-on-insulator substrate and after heat treating the source substrate and the support substrate to stabilize the bond between the source substrate and the support substrate.

31. The method of claim 14, further comprising selecting the insulator layer to comprise at least one of an oxide, a nitride, and an oxynitride.

32. The method of claim 14, wherein applying an electrical voltage to the at least one insulator-free accessible area of the support substrate so as to make an electrical connection contact on the support substrate of the semiconductor-on-insulator substrate comprises testing the semiconductor-on-insulator substrate.

33. A semiconductor-on-insulator substrate, comprising:
a support substrate including a semiconductor material and having a front face and a rear face;
an insulator layer covering the support substrate; and
an active layer including a semiconductor material positioned on the support substrate such that a portion of the insulator layer is buried between the active layer and the front face of the support substrate;
wherein at least one portion of the support substrate is free of the insulator such that the at least one portion is exposed, at least one portion of the rear face of the support substrate being covered with a portion of the insulator layer, the support substrate having a warpage of less than or equal to 50 μm.

34. The semiconductor-on-insulator substrate of claim 33, wherein the portion of the insulator layer covering the at least one portion of the rear face of the support substrate extends over at least 50% of a surface area of the rear face.

35. The semiconductor-on-insulator substrate of claim 33, wherein the portion of the insulator layer buried between the active layer and the front face of the support substrate has a thickness of at least 0.2 μm.
